(19) United States
(12) Patent Application Publication
(10) Pub. No.: US 2005/0149786 A1
(43) Pub. Date: Jul. 7, 2005

(54) Apparatus and method for determining threshold voltages in a flash memory unit

(76) Inventors: Mohamed A. Hassan, Sugar Land, TX (US); Lich X. Dang, Houston, TX (US); David A. Mondeel, Plano, TX (US)

Correspondence Address: TEXAS INSTRUMENTS INCORPORATED, P O BOX 655474, M/S 3999, DALLAS, TX, 75265, US

(21) Appl. No.: 10/741,384

(22) Filed: Dec. 19, 2003

(51) Int. Cl. G01R 31/28

(52) U.S. Cl. 714/724

(57) ABSTRACT

In an integrated circuit having a processing core and at least one memory unit, each memory unit, in addition to the storage cells and addressing circuits, includes apparatus for testing the memory independently from the testing of the processing core. The test apparatus includes a local storage unit to store test procedures and a local processing unit for independently executing the test procedures in response to external control signals. Stress voltages can be applied to the storage cell terminals to determine viability of the storage cell structure. The incorporation of test apparatus as part of the memory permits a tested integrated circuit to be provided that is less expensive than a memory unit that is tested by external test and debug apparatus. The test apparatus permits a threshold voltage for the change in the identification of a stored logic state to be determined in the absence and the presence of a stress voltage without intervention of external signals. The difference between the threshold voltages without and with the application of a stress voltage provides a parameter related to the stability of operation of the storage cell.

### BACKGROUND OF THE INVENTION

1. Field of the Invention

This invention relates generally to integrated circuit devices and, more particularly, to the testing of memory systems on integrated circuit devices. The testing technique can be applied to programmable non-volatile memory units such as Flash memory units.

2. Background of the Invention

In the present state of integrated circuit technology, programmable, non-volatile memory units, such as Flash memory units have become increasingly important. These memory units have been in integrated circuits devices. Referring to FIG. 1, an integrated circuit device 10 can include a processing core 11 and at least one memory unit 151-153. The processing core 11, for purposes of this discussion includes the central processing unit, random access memory, peripheral units, buses, etc. for the integrated circuit device 10. Each of the memory unit(s) 151-153 exchanges signal groups with the processing core. 11. For purposes of this discussion, each of the memory units, for example memory unit 151, includes a storage array 1511 and a charge pump 1512. The storage cell array 1511 includes multiplicity storage cells, each cell storing a bit of binary information, and a detector for determining the logic state of the storage cells. Because the operation of the typical programmable, non-volatile memory cells requires voltage levels in excess of the voltage levels normally available for an integrated circuit device, a charge pump 1512 is provided. The charge pump 1512 is designed to take the voltage levels available for the integrate circuit device 10 and increase (i.e., “pump”) voltage levels to a magnitude that can result in the operation of the storage cells.

Referring to FIG. 2, the principal components of a Flash memory storage cell are illustrated. The storage cell 20 has a source terminal 21, bit line terminal 22, and a word line terminal 23. Located between the terminal coupled to the word line terminal 23 and the region coupling the bit line terminal 22 and the source terminal 21 is a floating gate 24. The operation of the memory cell 20 can be understood as follows. By proper biasing of the terminals, a charge can be stored on the floating gate 24. The amount of charge stored on the floating gate 24 of a properly biased bit cell 20 can determine the amount of charge flowing between the source terminal 21 and the bit line terminal 22 during a read operation. The amount of the charge flowing between the terminals can represent a logic state. The bit line terminal is coupled to a charge (logic state) detector 29. In a read operation, the detector 29 determines the logic state by the amount of charge transferred through the storage cell 20 under read operation conditions. Table 1 illustrates the conditions for the various operations on the storage cell according to one implementation of Flash memory storage cell.

TABLE 1

| OPERATION | SOURCE | WORD LINE | BIT LINE |
|---|---|---|---|
| READ | 0 volts | 5 volts | 1 volt |
| WRITE | 0 volts | 11.4 volts | 5.8 volts |
| ERASE | 5.8 volts | −8.2 volts | FLOAT |

The successful operation of the storage bit cell 20 depends on the ability of the floating gate 24 to retain the charge without excessive decay. Excessive decay of the stored charge can result in the improper identification of the logic state that has been written into the bit cell 20. The testing of the programmable, non-volatile bit cells is therefore elaborate, requiring the simulation of conditions that would result in erroneous operation. One of the causes of storage cell failure is the mobility of charge to or from the floating gate. Instead of waiting a period of time for movement of the charge, an over-voltage or stress voltage is applied bit cell to expedite the testing. The stress voltage provides enhanced mobility of the stored charge without the need to wait for a long period of time. After the stress voltage has been applied the storage cell is tested to see if the increased mobility of the charge on the floating gate has resulted in a change of the stored logic state. A change in the stored logic state indicates that the storage cell is defective and should not be used by the processing core 11. To test the storage cell, the source line, the bit line 32 and the word line 23 individually have stress voltage applied thereto in the test procedures to determine the effect on charge stored or erased from the floating gate. The change in the charge stored on the floating gate can be determined by a read of the logic state represented by the charge. In addition, the word line voltage can be varied to determine the change in the threshold voltage wherein the incorrect logic state is identified during a read operation.

In the past, the storage cells of the memory units have been tested by external test apparatus. For example, in FIG. 1, the external connections to test apparatus are labeled 1515, 1525, and 1535, respectively. By means of the external connections, the operation of the programmable, non-volatile memory units could not be tested independently of the core processor 11 without additional device pins. The testing could be controlled, the proper voltages could be applied to the leads of the storage cell, and the results of the procedures applied to the external apparatus for testing. This technique did not permit the testing to be performed in parallel without additional device pins. In addition, the several additional voltage levels needed to adequately test the storage cells have been provided by the external testing apparatus. However, the exchange of signals needed to configure the memory unit for several test procedures and to report the result of the test procedures has proven to be time-consuming. Because the length of the test procedures impacts the cost of the circuit board, the testing procedures described above have proven too expensive. In addition, the number of pins to provide the exchange of signals and the voltage levels for testing purposes has proven to be excessive. It will be clear that, while the foregoing description for testing configurations has been described with respect to only one storage cell, the typical testing configuration will typically include a plurality of storage cells such a the storage cells required to store, for example, a word of data. When one storage cell is found to be defective, the whole plurality of storage cells will be considered defective.

A need has therefore been felt for apparatus and an associated method having the feature that the time to test to a memory unit would be reduced. It would be another feature of the apparatus and associated method to provide a tested integrated circuit device, the integrated circuit device having a memory unit, at a reduced cost. It would be yet another feature of the apparatus and associated method to reduce the number of pins on the circuit board required to test the memory unit. It would be still another feature of the apparatus and associated method to provide for testing apparatus for each memory unit of the integrated circuit device. It would be yet a further feature of the apparatus and associated method to provide a controllable charge pump responsive to the provided testing apparatus. It would be yet another feature of the apparatus and associated method to provide as part of the memory unit a processing unit with an associated memory unit that controls the testing of the memory in response to external control signals. It would be a still further feature of the apparatus and associated method to provide the results of the testing of the memory unit to external apparatus. It would be a still further feature of the apparatus and associated method to determine the effect of a stress voltage on the logic state stored in the storage cell. It would be a still more particular feature of the apparatus and associated method to determine the difference between the voltage levels at which a change in the identification of a stored logic state with and without application of a stress voltage level. It would be yet another feature of the apparatus and associated method to permit the identification of threshold voltages for the storage cells.

### SUMMARY OF THE INVENTION

The aforementioned and other features are provided, according to the present invention, by the incorporation in the memory unit of testing apparatus needed to test the memory in the memory itself. The testing apparatus includes a memory unit for the storage of software procedures necessary to test the memory unit. A processing unit controls the selection and sequencing of the software procedures in response to external control signals. The local processing unit also provides the control of the addressing apparatus to exercise the storage cells in a predetermined and systematic manner. Because memory units, such as Flash memory units, typically require voltages different from the voltage levels available on the circuit board, a programmable charge pump is used to raise the voltage to a level compatible with the operation of the memory storage cells and to provide the voltages necessary for testing the memory unit. The charge pump, in response to control signals from the processing unit, provides the correct voltages to the terminals of the plurality of storage cells under test. The control of the charge pump by the processing unit includes the ability to provide a step function for determining threshold voltage. The testing logic includes apparatus for the storage of test results, the test results being transferred to external apparatus in response to control signals. According to one test procedure, a logic state is stored in a storage cell, a stress voltage is applied to a selected terminal of the storage cell and the effect on the stored logic state is determined. According to a separate test procedure, the difference between the voltage levels at which a change in the identification of a stored logic state (i.e., threshold voltages) with and without application of a stress voltage level can be determined and used to identify the stability of the storage cell.

Other features and advantages of present invention will be more clearly understood upon reading of the following description and the accompanying drawings and the claims.

### BRIEF DESCRIPTION OF THE DRAWINGS

FIG. 1 is a block diagram of an integrated circuit board having at least one programmable, non-volatile memory unit.

FIG. 2 illustrates the components of Flash memory cell according to the prior art.

FIG. 3 is a block diagram of the components of the storage unit according to the present invention.

FIG. 4 is a block diagram illustrating the coupling of the charge pump to a storage cell during test and debug procedures according to the present invention.

FIG. 5A illustrates the storage cell voltages for storing charge on the floating gate, FIG. 5B illustrates the storage cell voltage for determining the threshold voltage of the storage cell, and FIG. 5C illustrates the word line voltages for determining the threshold voltage.

FIG. 5A through FIG. 5C illustrate the procedure for determining a threshold voltage for a storage cell having a charge stored therein according to the present invention.

FIG. 6A through FIG. 6C illustrate the procedure for determining a threshold voltage for a storage cell having a charge stored therein and thereafter a stress voltage has been applied to the bit line according to the present invention.

FIG. 7A through FIG. 7C illustrate the procedure for determining a threshold voltage for a storage cell having a charge stored therein and thereafter a stress voltage has been applied to the word line according to the present invention.

FIG. 8A through FIG. 8C illustrate the procedure for determining a threshold voltage for a storage cell having a charge stored therein and thereafter a stress voltage has been applied to the source terminal according to the present invention.

FIG. 9A through FIG. 9F illustrate the procedure to determining a threshold voltage for a storage cell having the charge removed there from and thereafter a stress voltage has been applied to the word line according to the present invention.

### DESCRIPTION OF THE PREFERRED EMBODIMENT

1. Detailed Description of the Figures

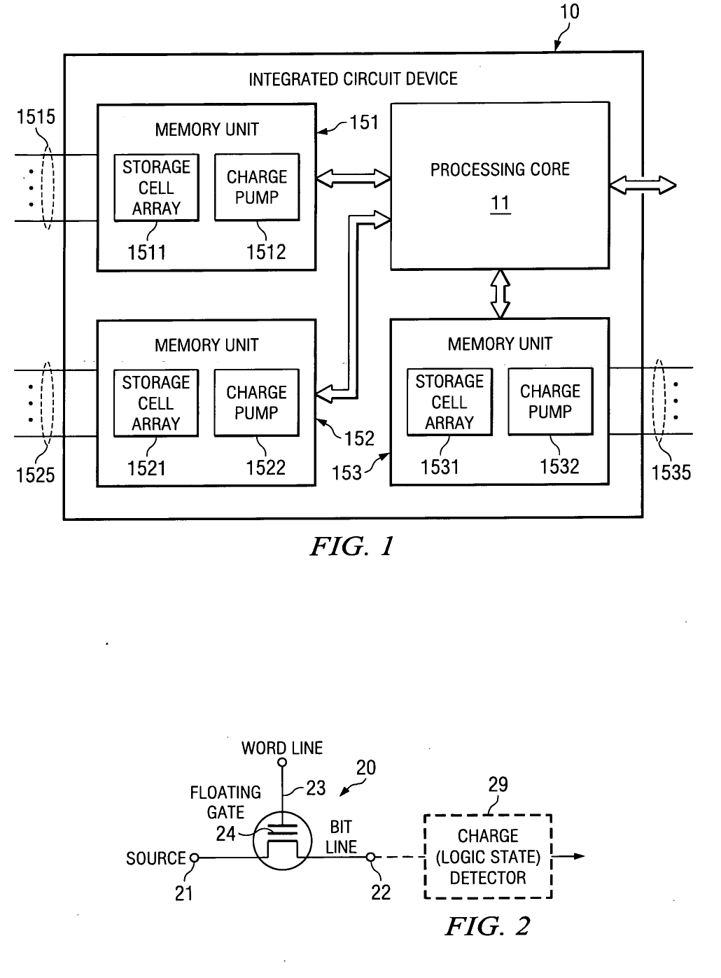

FIG. 1 and FIG. 2 have been described with respect to the related art.

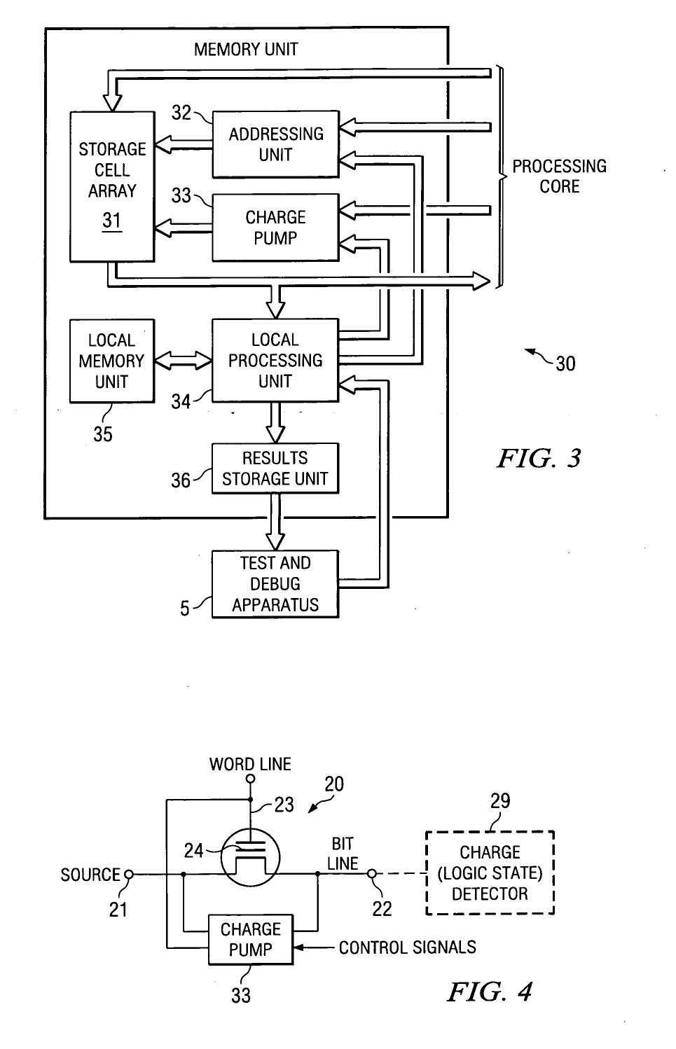

Referring next to FIG. 3, the apparatus for the storage and retrieval of signal groups along with apparatus for testing the memory unit 30 according to the present invention is shown. The memory unit 30 has a storage cell array 31 in which the logic signals are received from the processing core 11 and stored, for example, as charges on the floating gates of the cells of the array. In response to signals from the processing core 11, the addressing unit 32 accesses sub-set of the storage cells, e.g., a sub-set storing a group of logic signals. In response to the access of the sub-array, the logic signals from the processing core are stored in the addressed locations of the storage cell array 31 in response to write control signals from the processing core 11. In response to read control signals from the processing core, logic signals stored in the addressed sub-array are transferred to the processing core 11. The voltage levels needed for the operation of the memory unit are higher than the voltage levels generally available for the integrated circuit device within which the memory 30 has been fabricated. A charge pump 33 is coupled to a power source on the circuit board and provides a voltage appropriate to the operation of the storage cell array in response to control signals from the processing core 11. In the testing operations, the local processing unit 34 receives control signals from the test and debug apparatus 5. In response to the control signals from the test and debug apparatus 5, the local processing unit 34 executes procedures stored in the local memory unit. 35. In executing these procedures, the local processing unit 34 applies control signals to the addressing unit 32 and to the charge pump 33. The results of the test procedures are applied to the local processing unit 34 and are stored in the results storage unit 36. The test results stored in the results storage unit 36 can be transferred to the test and debug apparatus 5 for further evaluation.

The charge pump 33 of the present invention is implemented to provide all the voltages required for the operation of the storage cells including the additional voltages needed for the testing operations. In this manner, no external voltages need to be introduced testing of the memory further reducing the number of leads. The charge pump 33 is designed so that, in response to control signals, the voltage level applied to the word line can have a step function configuration for the threshold tests.

Referring to FIG. 4, the storage cell of FIG. 2 is shown. However, in place of the external voltage leads needed to activate the terminals of the storage cell, the charge pump 33 is designed to provide, in response to control signals from the local processing core 34, the proper bias and stress voltages for the test procedures. In the present invention, the control signals original with the local processing unit during the test and debug procedures.

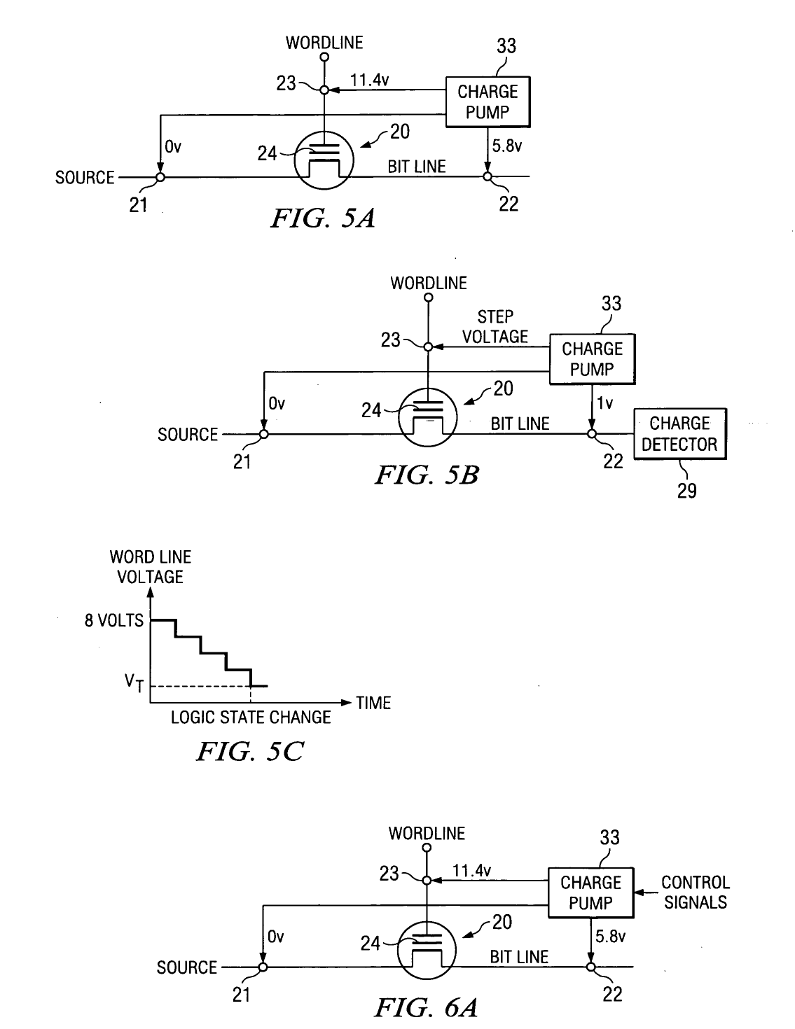

Referring to FIGS. 5A-5C, the process for determining the threshold voltage (down) V_{T}(D) for a storage cell having a charge stored on the floating gate is illustrated. In FIG. 5A, the voltages applied to the storage cell to provide a charge on the floating gate that will result in a first logic state being detected is illustrated. In FIG. 5B, the voltages applied to the storage cell to determine a threshold voltage is shown. FIG. 5C provides a detailed example of the word line voltage as a function of time. During normal read operation, with 8 volts applied to the word line, the stored logic state will be identified by the charge detector. The word line voltage is then lowered in increments until the charge detector detects the opposite logic state. Referring to FIG. 5C, the threshold voltage V_{T} is the word line voltage at which the charge detector identifies a different logic state during read operation.

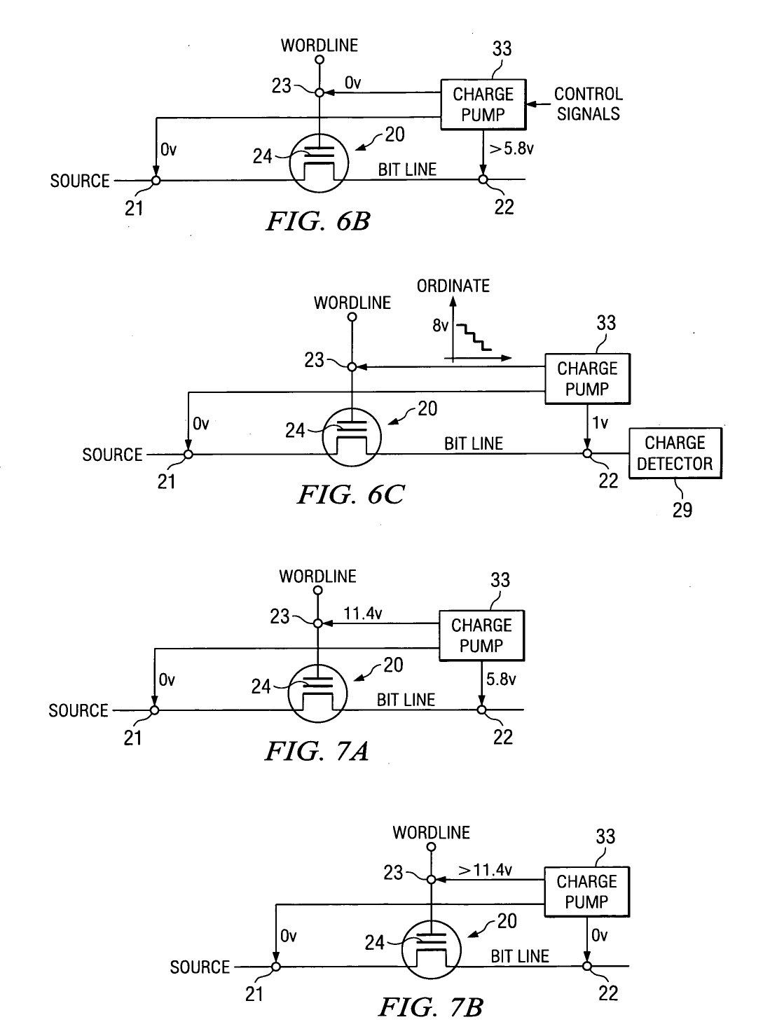

Referring to FIG. 6A-FIG. 6C, a procedure for identifying the effect of a stress voltage is illustrated. In FIG. 6A, a charge is deposited on the floating gate of the storage cell 20 using the voltage values given in Table 1, the charge defining a logic state stored in the storage cell 20. In FIG. 6B, a stress or over-voltage is applied to bit line of the storage cell. In the example shown in FIG. 6B, the over-voltage is greater than 5.8 volts. In FIG. 6C, the threshold voltage V_{T} is determined in the manner described with respect to FIGS. 5B and 5C. Because of the application of the stress voltage, the threshold voltage determined after application of the stress voltage will be different from the threshold voltage determined after a normal write operation. The difference between the two threshold voltages, ΔV_{T}, is an indication of the stability of the charge stored on the floating gate with respect to the application of a stress voltage on the word line terminal of the storage cell. ΔV_{T} will also be a function of the value of the stress voltage. In tests to determine the stability of the charge on the floating gate, standardized values will be used. This test and debug procedure is performed under the control of the local processing unit.

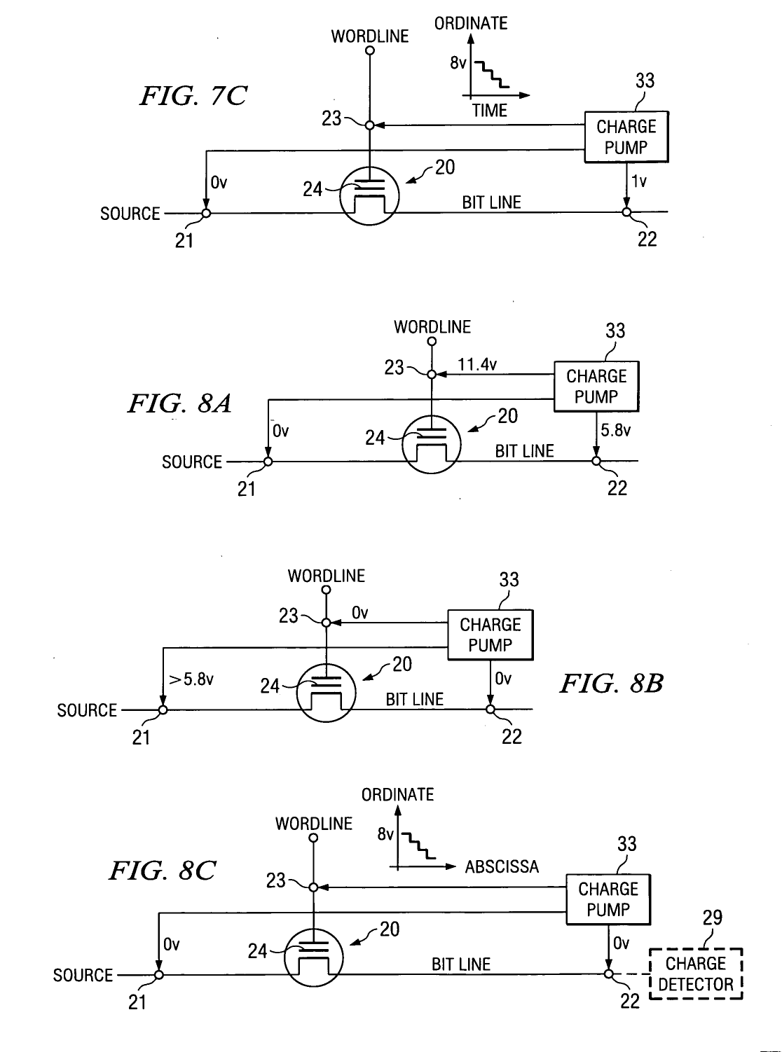

Referring to FIGS. 7A-7C and FIG. 8A-FIG. 8C, the same type of stress or over-voltage test is applied to the word line and to the source terminal, respectively. In FIG. 7A and FIG. 8A, a charge defining a selected logic state is written on the floating gate according to the parameters of Table 1. In FIG. 7B, a stress voltage, greater than 11.4 volts, is applied to the word line terminal, while in FIG. 8B, a stress voltage greater than 5.8 volts is applied to the source terminal of a storage cell 20. In FIG. 7C and FIG. 8C, the threshold voltages after stress voltages have been applied to the logic state of the storage cell are determined, thereby determining the voltage level at which the stored logic state no longer represented the originally stored logic state. With the threshold voltages for both the normal read operation and the threshold voltages after the stress voltages were applied to the storage cell, the change in the threshold voltages ΔV_{T} resulting from the application of the stress voltages to the word line and the source terminal can be determined. The ΔV_{T} parameter can provide an indicia of the mobility of the charge stored on the floating gate. This test and debug procedure is controlled by the local processing unit.

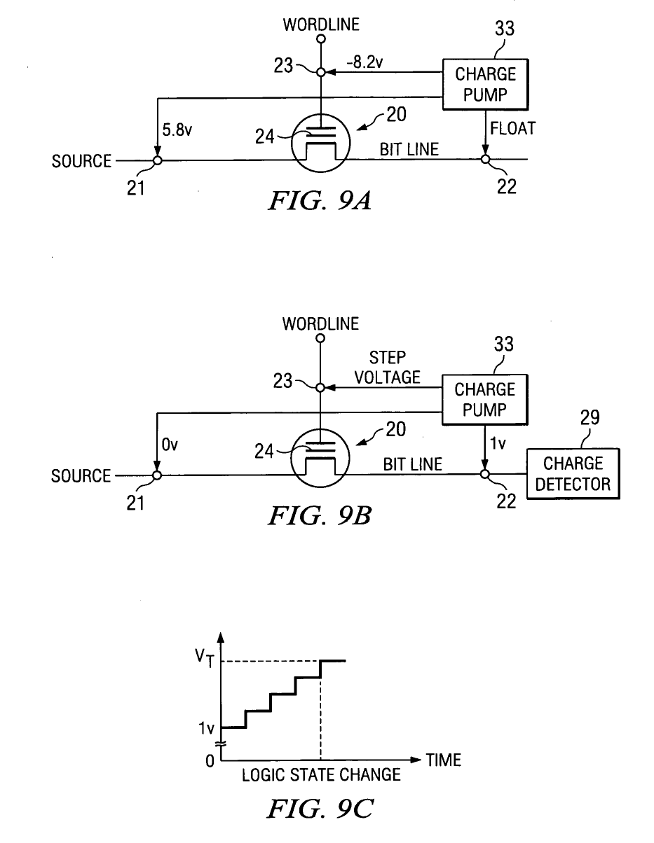

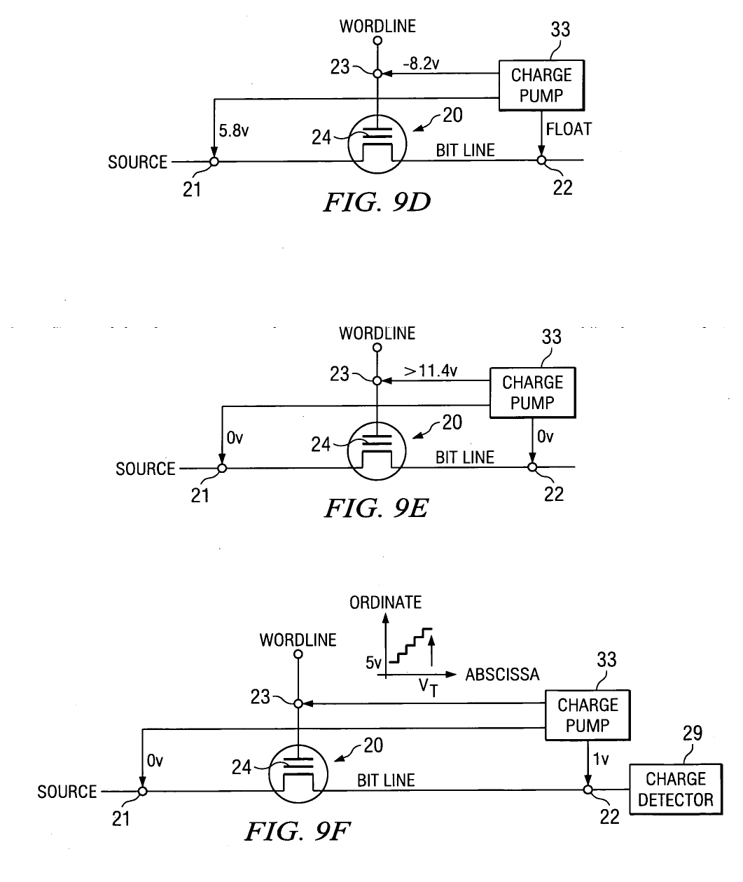

Referring to FIGS. 9A-9E illustrates the determination of a determination of a threshold value difference arising from and over voltage applied to a storage cell from which the charge has been erased from the from the floating gate. In FIG. 9A, the charge is erased from floating gate using parameters described in Table 1. In FIG. 9B, the threshold voltage V_{T} is determined using the voltage increments from the charge pump illustrated in FIG. 9C. In FIG. 9D, the charge is erased from the floating gate. In FIG. 9E, a stress voltage is applied to the word line. In FIG. 9F, the determination of the threshold voltage after the storage cell has had a stress voltage applied thereto is illustrated. The difference between the threshold voltages as determined in FIG. 9B and FIG. 9F provide the ΔV_{T}, the parameter defining the mobility of the charge on the floating gate.

2. Operation of the Preferred Embodiment

It has been found that when the length of time for testing an memory unit is taken into account, the provision of a tested integrated circuit device having a Flash memory unit is less expensive when the testing facilities are included as part of the memory unit. In addition, because processing core 11 shares pins with the memory test function, parallel testing can not be performed. This invention eliminates the shared pin requirement. Therefore, the processing core and memory unit can be tested in parallel. By incorporating the testing apparatus in the template for each memory, the number of memory units associated with each processing core can be varied with a minimum of design change for each memory configuration.

The use of the over-voltage or stress tests provides a measure of the stability of the charge stored on the floating gate. The stress voltage can be used to increase the mobility of the stored charge from the floating and thus can simulate the movement of charge over a relatively long period of time in a relatively short period of time. These tests can be controlled by the local processing unit and associated apparatus, thereby expediting the test and debug procedure.

The parameters, such as the voltage levels shown in Table 1, are provided for purposes of illustration. As will be clear to those skilled in the art, these parameters depend on the processes and materials that are used in fabricating the devices. Thus, other parameters can be used without departing from the present invention.

While the stress tests can provide information about the mobility of the storage of charge on the floating gate, a more sensitive tests compares the effect of a given stress voltage on the threshold voltages, i.e., the voltages at which the identification of the logic state defined by the stored charge is changed during a read operation. This parameter, ΔV_{T} provides a technique for the comparison of a stress voltage on the mobility of the charge on the floating gate and therefore of the stability of operation of the of the charge.

In the preferred embodiment, the external test and debug apparatus is used to enable the test procedures into the local memory unit. The execution of the test procedures is controlled by the local processing unit. The external test and debug apparatus can also analyze and respond to the results of the testing procedures. For example, the failure of at least one of group of memory bits can be responded to by rendering that group of storage cells inaccessible to the core processor and/or replacing access to the faulty group of memory cells with access to a group of functional cells.

Because of the limited set of signals that must be exchanged between the internal test apparatus in the memory unit and external test and debug apparatus in the present invention, the number of pins for coupling the memory unit to the external test apparatus is reduced as compared to the number of pins required when no test apparatus is included in the memory unit.

In the foregoing description, the testing of the Flash memory unit has been described. However, the techniques of this invention are applicable to other memory implementations.

While the invention has been described with respect to the embodiments set forth above, the invention is not necessarily limited to these embodiments. Accordingly, other embodiments, variations, and improvements not described herein are not necessarily excluded from the scope of the invention, the scope of the invention being defined by the following claims.

1. For use in an integrated circuit having a processing core and a memory unit, the memory unit comprising:
a plurality of storage cells, each storage cell including a detector for determining a logic state of cell;
an addressing unit for selecting at least one storage cell;
a memory unit for storing test procedures;
a processing unit coupled to the addressing unit and the memory unit, the processing unit implementing the test procedures under the control of externally applied signals; and.
a charge pump coupled to the processing unit, the charge pump applying voltage levels to the terminals of the storage cell, the voltage levels determined by control signals from the processing unit, the charge pump applying a sequence of read operation signals to the storage cell, the charge pump applying a stress voltage to a selected terminal of the storage cell.

2. The memory unit as recited in claim 1 wherein a threshold voltage is determined by the memory unit, the threshold voltage determining when during the sequence of read operation signals the identified logic state changes.

3. The memory unit as recited in claim 2 wherein a threshold voltage is determined before and after the application of a stress voltage.

4. The memory unit as recited in claim 3 wherein determining a threshold voltage includes:
a. storing indicia of a logic state in a storage cell;
b. applying read operation signals to the storage cell;
c. determining a logic state of the storage cell;
d. applying read operation signals to the storage cell wherein a selected one of the read operation signals has been incremented;
e. determining a logic state of the storage cell;
f. when the logic state of determined in e is different from the logic state determined in e, identifying the voltage level of the selected one read signal; and
g. when the logic state determined by e is the same as the logic state determined by f, returning to d.

5. The memory unit as recited in claim 4, wherein between a and b, applying a stress voltage to a selected terminal of the storage cell.

6. The memory as recited in claim 1 wherein the memory unit is implemented in Flash technology.

7. A method for testing a memory unit forming part of an integrated circuit, the memory unit including an array of programmable non-volatile storage cells, the method comprising:
including test apparatus for testing the memory unit as part of the memory unit;
storing test procedures in the test apparatus;
applying control signals from the test apparatus to a charge pump and a charge detector, and
determining a threshold voltage for the storage cell.

8. The method as recited in claim 7 further including determining threshold voltage after applying a stress voltage to a selected terminal of the storage cell.

9. The method as recited in claim 7 wherein determining a threshold voltage further includes;
storing indicia of a logic state in a storage cell;
by a read operation, identifying the logic state of the storage cell;
incrementing selected voltage level applied to the storage cell during a next read operation;
determining the next logic state of the storage cell during the next read operation; and
repeating the incrementing and determining steps until the identified logic state of the storage cell changes.

10. The method as recited in claim 8 further including applying a stress voltage to a selected terminal between storing indicia and identifying the logic state.

11. The method as recited in claim 7 further including the step of implementing the memory unit in Flash memory technology.

12. In an integrated circuit device having a processing core, at least one non-volatile programmable memory unit coupled to the processing core, the memory unit comprising:
a local processing unit;
a local memory unit, the local memory unit providing software procedures to the local memory unit;
a storage cell array for storing indicia of logic states, the storage cells including a detector for identifying a logic state during a read operation;
a charge pump, the charge pump providing preselected voltage levels to terminals of at least one storage cell of the storage cell array in response to control signals from a one of the processing core and the local processing unit; and
an addressing unit, the addressing unit responsive to control signals from a one of the processing core and the local processing unit for selecting the at least one storage cell;
wherein threshold voltage is determined for at least one storage cell.

13. The memory unit as recited in claim 11 wherein the threshold voltage is determined for a storage cell that has had a stress voltage applied thereto.

14. The memory unit as recited in claim 12 wherein determining a threshold voltage includes:
storing indicia of a logic state in a storage cell;
during series of read operations, incrementing a selected voltage during each read operation; and
identifying the logic state during each read operation;
determining the level of the selected voltage at which the identified logic state changes from read operation to read operation.

15. The memory unit as recited in claim 13 wherein a selected terminal of the storage cell has a stress voltage applied thereto after the storing of the indicia and the first read operation.

16. The memory unit as recited in claim 11 wherein the memory unit is a Flash memory unit.

17. The memory unit as recited in claim 11 wherein the local processing unit operates under control of external test apparatus.
